(19) United States
(12) Patent Application Publication
(10) Pub. No.: US 2017/0278466 A1
(43) Pub. Date: Sep. 28, 2017

(54) SHIFT REGISTER UNIT, METHOD FOR DRIVING THE SAME, RELATED GATE DRIVER CIRCUIT, AND RELATED SEMICONDUCTOR DEVICE

(71) Applicants: BOE TECHNOLOGY GROUP CO., LTD, Beijing (CN); BEIJING BOE DISPLAY TECHNOLOGY CO., LTD., Beijing (CN)

(72) Inventors: Haifeng YU, Beijing (CN); Haiqin HUANG, Beijing (CN); Junwei WANG, Beijing (CN)

(21) Appl. No.: 15/509,236

(22) PCT Filed: Oct. 11, 2016
(86) PCT No.: PCT/CN2016/101789

§ 371 Date: Mar. 7, 2017

(30) Foreign Application Priority Data
Oct. 19, 2015 (CN) 201510679991.5

(51) Int. Cl. G09G 3/36; G11C 19/28; G09G 3/32; G09G 3/20; G02F 1/1333

(52) U.S. Cl. CPC G09G 3/36; G09G 3/2096; G02F 1/1333; G09G 3/32; G11C 19/287

(57) ABSTRACT

The present disclosure provides a shift register unit. The shift register unit includes an input module, a first resetting module, an energy storage module, a first enhanced resetting module, an output control module, a first input terminal, a second input terminal, a third input terminal, a fourth input terminal, a fifth input terminal, a sixth input terminal, a shift driving signal output terminal, and a first node. A first terminal of the energy storage module is connected to the first node. The input module is connected to the first node, the first input terminal, and the second input terminal. The output control module is connected to the first node, the third input terminal, and the shift driving signal output terminal. The first resetting module is connected to the first node, the fourth input terminal, and the fifth input terminal.

### CROSS-REFERENCES TO RELATED APPLICATIONS

This PCT patent application claims priority of Chinese Patent Application No. 201510679991.5, flied on Oct. 19, 2015, the entire content of which is incorporated by reference herein.

### TECHNICAL FIELD

The present invention generally relates to the display technologies and, more particularly, relates to a shift register unit, a method for driving the shift register unit, a related gate driver circuit, and a related semiconductor device.

### BACKGROUND

As liquid crystal display (LCD) devices advance, LCD devices with high resolution and narrow bezel become a main trend in the development of LCD devices. The use of gate shift register units in display panels is an important means to realize narrow bezel and high resolution in LCD devices.

Drivers of a thin film transistor-liquid crystal display (TFT-LCD) mainly include gate driver circuits and data driving circuits. A gate driver circuit mainly includes multiple levels of shift register units and signal lines connecting each shift register unit. The shift register unit of each level is connected to a gate line. The output signals of shift register units are used to scan and drive the pixel TFTs row by row.

In a conventional shift register unit, an enhanced rescuing control module is used to reset the voltage at the node (referred as PU) connected to the control terminal of an output control module. The enhanced resetting control module often includes a plurality of transistors. The plurality of transistors takes up an undesirably large layout area in the corresponding shift register unit.

### BRIEF SUMMARY

The present disclosure provides a shift register unit, a method for driving the shift register unit, a related gate driver, and a related semiconductor device. By using the disclosed shift register unit and applying the disclosed method, the shift register units in a gate driver may take up a smaller layout area.

One aspect of the present disclosure includes a shift register unit. The shift register unit includes an input module, a first resetting module, an energy storage module, a first enhanced resetting module, an output control module, a first input terminal, a second input terminal, a third input terminal, a fourth input terminal, a fifth input terminal, a sixth input terminal, a shift driving signal output terminal, and a first node. A first terminal of the energy storage module is connected to the first node. The input module is connected to the first node, the first input terminal, and the second input terminal. The output control module is connected to the first node, the third input terminal, and the shift driving signal output terminal. The first resetting module is connected to the first node, the fourth input terminal, and the fifth input terminal. The first enhanced resetting module is connected to the first node and the sixth input terminal.

Optionally, when an effective turn-on voltage is applied at the second input terminal, the input module turns on to write a pulse signal of a first level applied by the first input terminal to the first node, sets a voltage at the first node to the first level, and charges the first terminal of the energy storage module; the output control module outputs a shift driving signal to the shift driving signal output terminal based on a first clock signal applied on the third input terminal when a voltage at the first node is of the first level. When a resetting signal is applied on the fourth input terminal, the first resetting module sets the voltage at the first node to a second level based on a voltage of the second level applied on the fifth input terminal; and when the voltage at the first node is of the second level and the input module is turned off the enhanced resetting module sets the voltage at the first node to be of a level of a voltage applied on the sixth input terminal.

Optionally, the fifth input terminal and the sixth input terminal are a same input terminal.

Optionally, the shift register unit further includes a second resetting module, a seventh input terminal, and an eighth input terminal, a second terminal of the energy storage module being connected to the shift driving signal output terminal, the second resetting module being connected to the shift driving signal output terminal, the seventh input terminal, and the eighth input terminal. When an effective turn-on voltage of the second resetting module is applied on the seventh input terminal and a voltage of the second level is applied an the eighth input terminal, the second resetting module sets a voltage outputted by the shift driving signal output terminal to the second level.

Optionally, the eighth input terminal is a same input terminal with one or more of the fifth input terminal and the sixth input terminal.

Optionally, the seventh input terminal and the fourth input terminal are a same input terminal; and the effective turn-on voltage of the second resetting module and the rescuing signal are of the first level.

Optionally, the second resetting module includes a first transistor, being N-type, a gate electrode of the first transistor being connected to the seventh input terminal, a source electrode of the first transistor being connected to the shift driving signal output terminal, and a drain electrode of the fast transistor being connected to the eighth input, terminal, a turn-on level of the first transistor being the first level.

Optionally, the shift register unit further includes a second enhanced resetting module and a ninth input terminal. The second enhanced resetting module is connected to the first node, the ninth input terminal, and the shift driving signal output terminal; and the second enhanced resetting module resets the voltage outputted by the shift driving signal output terminal to the second level when the voltage at the first node is of the second level and the ninth input terminal is applied with a voltage of the second level.

Optionally, the ninth input terminal is a same input terminal with one or more of the fifth input terminal and the sixth input terminal.

Optionally, the second enhanced resetting module includes a second transistor, being P-type, a gate electrode of the second transistor being connected to the first node, a drain electrode of the second transistor being connected to the shift driving signal output terminal, a source electrode of the second transistor being connected to the ninth input terminal, and a turn-on level of the second transistor being the second level.

Optionally, the input module includes a third transistor, being N-type, a gate electrode of the third transistor being connected to the second input terminal, and a source electrode of the third transistor being connected to the first input terminal; or the gate electrode of the third transistor being connected to the first input terminal, and the source electrode of the third transistor being connected to the second input terminal, a drain electrode of the third transistor being connected to the first node, and a turn-on level of the third transistor being the first level.

Optionally, the first enhanced resetting module includes a fourth transistor, being P-type, a gate electrode and, a drain electrode of the fourth transistor being connected to the fast node, a source electrode of the fourth transistor being connected to the sixth input terminal, a width to length ratio of the channel of the fourth transistor being less than a width to length ratio of the channel of the third transistor, and a turn-on level of the fourth transistor being the second level.

Optionally, the output control module includes a fifth transistor, being N-type, a source electrode of the fifth transistor being connected to the third input terminal, a gate electrode of the fifth transistor being connected to the first node, a drain electrode of the fifth transistor being connected to the shift driving signal output terminal, and a turn-on level of the fifth transistor being the first level.

Optionally, the first resetting module includes a sixth transistor, being N-type, a source electrode of the sixth transistor being connected to the first node, a drain electrode of the sixth transistor being connected to the fifth input terminal, a gate electrode of the sixth transistor being connected to the fourth input terminal, a turn-on level of the sixth transistor being the first level.

Optionally, the first input terminal and the second input terminal are a same input terminal; and an effective turn-on voltage of the input terminal is of the first level.

Optionally, the energy storage unit is a capacitor.

Optionally, the first level is a high level and the second level is a low level.

Another aspect of the present disclosure provides a method for driving the disclosed shift register unit. The method includes: in a first phase, applying a voltage of an effective turn-on level for the input module on the second input terminal to turn on the input module, and applying a pulse signal of the first level on the first input terminal so that the input module sets the voltage at the first node to the first level, and the input module charging the first terminal of the energy storage module; in a second phase, when the voltage at the first node is of the first level, turning on the output control module, applying a first clock signal on the third input terminal to control the output control module to output a shift driving signal through the shift driving signal output terminal; and in a third phase, applying a reset signal on the fourth input terminal and applying a voltage of the second level on the fifth input terminal so that the first resetting module resets the voltage at the first node to the second level, and the first resetting module discharging to the first terminal of the energy storage module. In and after the third phase in a same frame, the voltage at the first node id of the second level, turning on the first enhanced resetting module so that the first enhanced resetting module sets the voltage at the first node to be the voltage applied on the sixth input terminal.

Another aspect of the present disclosure provides a gate driver circuit. The gate driver circuit includes a plurality of cascading shift register units disclosed by the present disclosure.

Another aspect of the present disclosure provides a semiconductor device. The semiconductor device includes one or more of the disclosed gate driver circuits.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a circuit diagram of a conventional shift register unit;

FIG. 2 illustrates a timing diagram of certain signals and levels of certain nodes in the conventional shift register unit illustrated in FIG. 1;

FIG. 3 illustrates a block diagram of an exemplary shift register unit according to various disclosed embodiments of the present disclosure;

FIG. 4 illustrates a block diagram of another exemplary shift register unit according to various disclosed embodiments of the present disclosure;

FIG. 5 illustrates a circuit diagram of an exemplary shift register unit according to various disclosed embodiments of the present disclosure; and

FIG. 6 illustrates a timing diagram of certain signals and levels of certain nodes in the shift register unit illustrated in FIG. 5.

### DETAILED DESCRIPTION

For those skilled in the art to better understand the technical solution of the invention, reference will now be made in detail to exemplary embodiments of the invention, which are illustrated in the accompanying drawings. Wherever possible, the same reference numbers will be used throughout the drawings to refer to the same or like parts.

In a shift register unit, when the node (referred as PU) connected to the control terminal of an output control module outputs a high voltage, the output control module may be turned on or connected. The output control module thus outputs a high-level shift driving signal. To prevent the output control module from outputting high level signals for more than once during one frame, after the output control module outputs a high-level shift driving signal, it is necessary to reset the voltage at PU to a low level. To prevent the voltage at PU from being pulled to a high level in one frame, e.g., caused by leakage current from modules (for example, input module) connected to the node PU, it is often necessary to keep resetting the voltage at PU in one frame.

To implement the resetting function, an enhanced resetting module and a control module for the enhanced resetting module are often arranged to reset the voltage at node PU. The control module for the enhanced resetting module can also be referred as an enhanced resetting control module. When the output control module outputs a high-level shift pulse signal, the enhanced resetting control module turns off the enhanced resetting module to avoid the enhanced resetting module from affecting the output control module. After one resetting process, the enhanced resetting control module turns on the enhanced resetting module to reset or enhance the resetting process of the voltage at node PU.

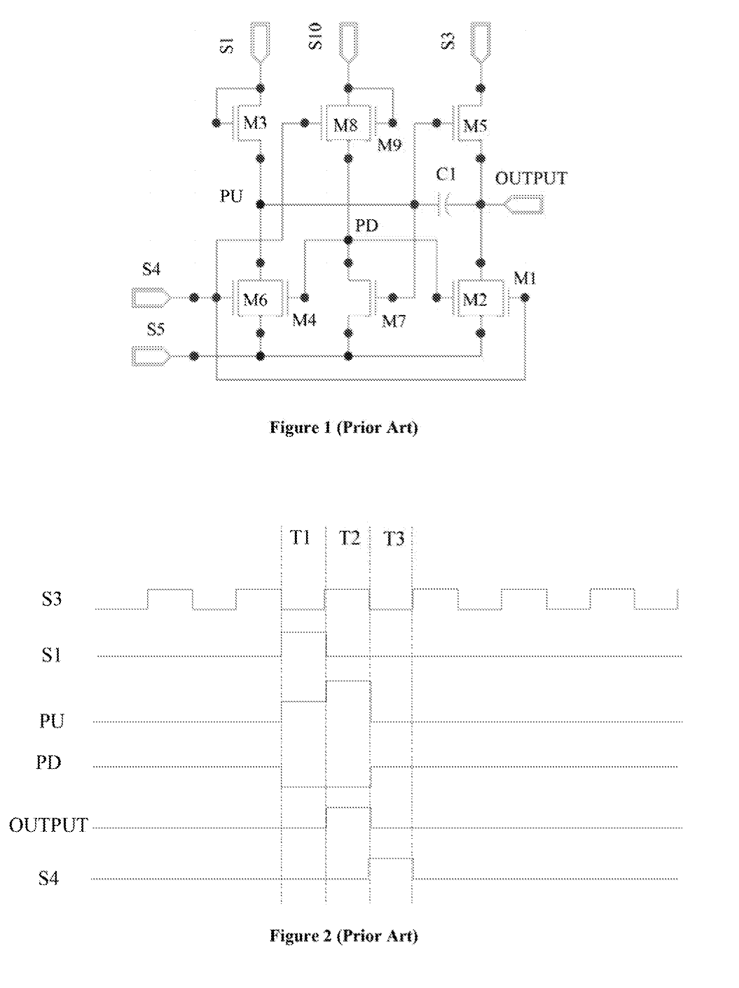

The exemplary structure of a conventional shift register unit is shown in FIG. 1. The shift register unit includes nine N-type transistors, i.e., M1-M9, and a capacitor C1. The shift register unit also includes input terminals S3, S10, S1, S4, and S5. The operation of the shift register unit shown in FIG. 1 can be illustrated by FIG. 2. In the driving process, a clock signal is applied on the input terminal S3, a high-level signal is applied on the input signal S10, and a low-level signal is applied on the input terminal S5. A high-level pulse signal is applied on the input terminals S1 and S4 at different times or phases.

in the first phase T1, a pulse signal is applied on the input terminal S1, and a low-level signal is applied on the input terminal S4. At this time, the transistor M3 is turned on, and the voltage at node PU is pulled up. The transistors M5 and M7 are turned on. Because a low-level signal is applied on the input terminal S1, the driving signal output terminal OUTPUT outputs a low-level signal. Because the transistor M7 is turned on, the voltage at node PD may be a low-level signal, which turns of the transistors M2 and M4. That is, the width to length ratio of the channel in transistor M7 may be greater than the width to length ratio of the channel in transistor M9, the transistor M7 thus has a stronger ability to pull down. In addition, because a low-level voltage is applied on the input terminal S4, transistors M1 and M6 are turned off. The gate electrode and the source electrode of transistor M9 are connected, and are both connected to input terminal S10, transistor M9 is thus kept on in all phases.

In the second phase T2, a low-level signal is applied on input terminals S1 and S4. At this time, transistors M5 and M7 are kept on, and except for transistor M9, all other transistors are turned off. Because a high-level signal is applied on the input terminal S3, the driving signal output terminal OUTPUT outputs a high-level signal. Because a high-level voltage is applied on the second terminal of the capacitor C1, the voltage at node PU undergoes an instantaneous change or increase.

In the third phase T3, a low-level signal is applied on the input terminal S1 to turn off transistor M3. A high-level signal is applied on the input terminal S4. At this time, transistors M6, M8, and M1 are turned on such that the voltage at node PU and the voltage outputted by the driving signal output terminal OUTPUT are pulled down. Because the voltage at node PU is pulled down, transistor M7 is turned off, and the voltage at node PD is increased. Transistors M4 and M2 are turned on. After transistors M4 and M2 are turned on, the voltage at node PU stays at a low-level, and transistors M7, M2 and M4 are kept on. Enhanced resetting of node PU can be implemented.

In the process described above, transistors M2 and M4 are used for enhanced resetting of the voltage at node PU, and functions as an enhanced resetting module. Transistors M7, M8, and M9 are used for enhanced resetting control functions, and together function as an enhanced resetting control module. To arrange such enhanced resetting control module or transistors require an undesirably large number of transistors in the shift register unit, and the enhanced resetting control module or transistors take up an undesirably large layout area.

One aspect of the present disclosure provides a shift register unit. In embodiments of the present disclosure, the shift register unit may apply enhanced resetting functions to the first node PU without an enhanced resetting control module. Thus, a smaller layout area is needed for the shift register unit. It is also easier for the display device incorporating the disclosed shift register unit to implement narrower bezel.

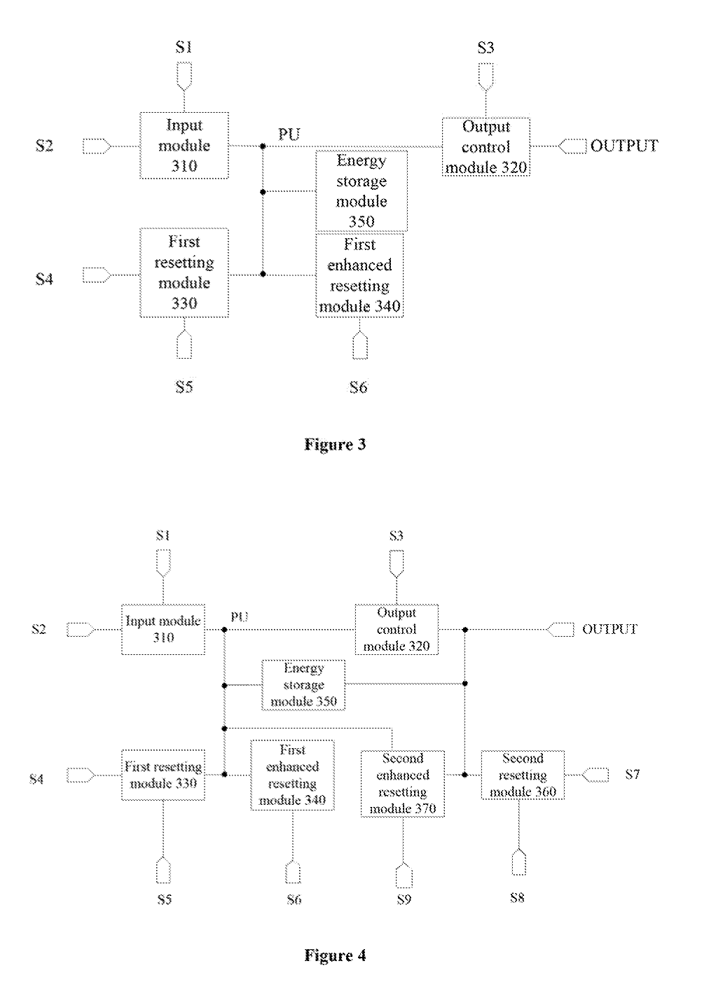

As shown in FIG. 3, the shift register unit may include an input module 310, an output control module 320, a resetting module 330, an enhanced resetting module 340, and an energy storage unit 350. The shift register unit may also include a driving signal output terminal OUTPUT, a first input terminal S1, a second input terminal S2, a third input terminal S3, a fourth input terminal S4, a fifth input terminal S5, and a sixth input terminal S6. A first terminal of the power storage module 350 may be connected to a first node PU.

The input module 310 may be connected to the first node PU the first input terminal S1, and the second input terminal S2. The input module 310 may be turned on when the second input terminal S2 inputs an effective turn-on signal, i.e., with an effective voltage level, such that the input module 310 may allow the pulse signal applied on the first input terminal S1 to be written into the first node PU. In this disclosure, an effective turn-on signal refers to a suitable or effective voltage with an appropriate level to turn on or enable a corresponding module or part. In some embodiments, the effective turn-on signal of a module/part may be the effective turn-on signal/voltage of the module/part. In this disclosure, the “effective turn-on signal/voltage” may be interchangeable with the “turn-on signal voltage”. The voltage at the first node PU may thus be set to be a first level. Meanwhile, the input module 310 may charge the energy storage module 350 through the first terminal of the energy storage module 350. The level of the pulse signal may be the first level.

The output control module 320 may be connected to the first node PU, the third input terminal S3, and the shift driving signal output terminal OUTPUT. The output control module 320 may be configured to control the shift driving signal output terminal OUTPUT to output a shift driving signal based on a first clock signal applied on the third input terminal S3, when the voltage at the first node PU is of the first level.

The first resetting module 330 may be connected to the first node PU, the fourth input terminal S4, and the fifth input terminal S5. Controlled by the resetting signal applied by the fourth input terminal S4, the first resetting module 330 may be configured to reset the voltage at the first node PU to a second level based on the voltage applied by the fifth input terminal S5. The first resetting module 330 may also discharge to the first terminal of the energy storage module 350. The resetting signal applied by the fourth input terminal S4 may be of the first level, and the voltage applied by the fifth input terminal may be of the second level. The second level may be lower than the first level.

The first enhanced resetting module 340 may be connected to the first node PU and a sixth input terminal S6. The first enhanced resetting module 340 may be configured to set the voltage at the first node PU to the voltage applied by the sixth input terminal S6 when the voltage at the first node PU is of the second level and the input module 310 is turned off.

The disclosed shift register unit may implement enhanced resetting functions to the first node PU without an enhanced resetting control module. Compared to a conventional shift register unit, which requires an enhanced resetting control module, a smaller layout area is needed for the disclosed shift register unit. It is thus easier for the display device incorporating the disclosed shift register unit to implement narrower bezel.

In some embodiments, the filth input terminal S5 and the sixth terminal S6 may be a same input terminal or share one input terminal. When the fifth input terminal S5 is applied with a voltage of the second level, the sixth input terminal S6 may also applied with a voltage of the second level. When a voltage of the second level is not applied on the fifth input terminal S5, a voltage of the second level is also not needed to be applied on the sixth input terminal S6. Thus, arranging the fifth input terminal S5 and the sixth input terminal S6 to be the same input terminal would not affect the output of the shift register unit, and the number of input terminals can be reduced. The number of signal fines used to drive the shift register unit can be reduced. It may be easier to arrange the layout of the corresponding gate driver circuit. The fabrication of the corresponding gate driver circuit may be easier.

FIG. 4 illustrates another disclosed exemplary shift register unit. As shown in FIG. 4, in some embodiments, a second terminal of the energy storage module 350 in the disclosed shift register unit may also be connected to the shift driving signal output terminal OUTPUT.

The disclosed shift register unit may further include a second resetting module 360, a seventh input terminal S7, and an eighth input terminal S8. The second resetting module 360 may be connected to the shift driving signal output terminal OUTPUT, the seventh input terminal S7, and the eighth input terminal S8. The second resetting module 360 may be turned on when the seventh input terminal S7 is applied with a voltage of the first level and the eighth input terminal S8 is applied with a voltage of the second level.

Thus, when the voltage of the shift driving signal output terminal OUTPUT is a shift pulse of the first level, the voltage at the first terminal of the energy storage module 350 may undergo an instantaneous change, i.e., changing to a higher voltage or to a lower voltage. For example, if the first level is a high level, the voltage at the first terminal of the energy storage module 350 may instantaneously change to a voltage of a higher level. If the first level is a low level, the voltage at the first terminal of the energy storage module 350 may instantaneously change to a voltage of a lower level. That is, the voltage at the first node PU may instantaneously change to a higher voltage or a lower voltage. Thus, the output control module 320 may have improved turn-on performance. The output control module 320 may more accurately control the shift driving signal output terminal OUTPUT to output the shift driving signal.

In some embodiments, the seventh input terminal S7 and the fourth input terminal S4 may be one input terminal or share a same input terminal. Accordingly, the effective turn-on level of the second resetting module 360 may be the same or consistent with the voltage level of the resetting signal applied on the first resetting module 330. For example, the effective turn-on level of the second resetting module 360 and the voltage level of the resetting signal may both be the first level. In this way, fewer signal lines may be used in the shift register unit. The layout area of the corresponding gate driver circuit may be reduced.

In some embodiments, the second resetting module 360 may include a transistor. For illustrative purposes, the transistor contained in the second rescuing module 360 may be a first transistor M1. The gate electrode of the first transistor M1 may be connected to the seventh input terminal S7. The source electrode of the first transistor M1 may be connected to the shift driving signal output terminal OUTPUT. The drain electrode of the first transistor M1 may be connected to the eighth input terminal S8. The turn-on level of the first transistor M1 may be the first level. In the present disclosure, the terms “first”, “second”, and the like are merely for illustrative purposes and do not indicate any difference in functions or structures.

As shown in FIG. 4, in some embodiments, the disclosed shift register unit may further include a second enhanced resetting module 370 and a ninth input terminal S9. The second enhanced resetting module 370 may be connected to the first node PU, the ninth input terminal S9, and the shift driving signal output terminal OUTPUT. The second enhanced resetting module 370 may be configured to reset the voltage outputted by the shift driving signal output terminal OUTPUT to the second level when the voltage at the first node PU is of the second level and the ninth input terminal S9 is applied with a voltage of the second level.

Specifically, the second enhanced resetting module 370 may include a P-type second transistor M2. The gate electrode of the second transistor M2 may be connected to the first node PU. The drain electrode of the second transistor M2 may be connected to the shift driving signal output terminal OUTPUT. The source electrode of the second transistor M2 may be connected to the ninth input terminal S9. The turn-on level of the second transistor M2 may be the second level.

In some embodiments, the ninth input terminal S9 may share the same input terminal with one or more of the fifth input terminal S5, the sixth input terminal S6, and the eighth input terminal S8. Thus, the number of signal lines for driving the shift register unit may be reduced. In some embodiments, the fifth input terminal S5, the sixth input terminal S6, the eighth input terminal S8, and the ninth input terminal S9 may be or may share a VSS terminal for providing a voltage of a second level.

In some embodiments, the input module 310 may include an N-type third transistor M3. The gate electrode of the third transistor M3 may be connected to the second input terminal S2, and the source electrode of the third transistor M3 may be connected to the first input terminal S1. Alternatively, the gate electrode of the third transistor M3 may be connected to the first input terminal S1, and the source electrode of the third transistor M3 may be connected to the second input terminal S2. The drain electrode of the third transistor M3 may be connected to the first node PU. The turn-on level of the third transistor M3 may be the first level.

In some embodiments, the first enhanced resetting module 340 may include a P-type fourth transistor M4. The gate electrode and the drain electrode of the fourth transistor M4 may be connected to the first node PU. The source electrode of the fourth transistor M4 may be connected to the sixth input terminal S6. The width to length ratio of the channel of the fourth transistor M4 may be less than the width to length ratio of the channel of the third transistor M3. The turn-on level of the fourth transistor M4 may be the second level.

The reason for applying a P-type second transistor M2 and a P-type fourth transistor M4 may include the follows. For example, the P-type second transistor M2 and the P-type fourth transistor M4 may ensure the voltage level at the first node PU maintain stable in a first phase and in a second phase of the operation (described in detail in the description of the method for driving, a shift register unit). Also, in the third phase, the P-type second transistor M2 and the P-type fourth transistor M4 may apply enhanced resetting functions on the first node PU and the shift driving signal output terminal OUTPUT. Thus, the voltage levels at the first node and the shift driving signal output terminal OUTPUT may be desirably pulled down.

In some embodiments, the output control module 320 may include a fifth transistor M5. The source electrode of the fifth transistor M5 may be connected to the third input terminal S3. The gate electrode of the fifth transistor M5 may be connected to the first node PU. The drain electrode of the fifth transistor M5 may be connected to the shift driving signal output terminal OUTPUT. The turn-on level of the fifth transistor M5 may be the first level.

In some embodiments, the first resetting module 330 may include a sixth transistor M6. The source electrode of the sixth transistor M6 may be connected to the first node PU. The drain electrode of the sixth transistor M6 may be connected to the fifth input terminal S5. The gate electrode of the sixth transistor M6 may be connected to the fourth input terminal S4. The turn-on level of the sixth transistor M6 may be the first level.

In some embodiments, the first input terminal S1 and the second input terminal S2 may be a same input terminal. The effective turn-on level of the input module 310 may be the first level. When the input module 310 needs to be turned on, the first input terminal S1 and the second input terminal S2 may both need to be applied with a voltage of the first level. When the input module 310 needs not be turned on, neither of the first input terminal S1 and the second input terminal S2 may need to be applied with a voltage of the first level. Thus, the first input terminal S1 and the second input terminal S2 may share or be combined to be a same signal input terminal. The normal operation of the shift register would not be impaired, and the number of signal lines for driving the shift register unit may be reduced.

It some embodiments, the energy storage module 350 may be a capacitor or other suitable devices for storing energy.

In some embodiments, the first level may be a high level, and the second level may be a low level. The first transistor M1, the third transistor M3, the fifth transistor M5, the sixth transistor M6 may be N-type transistors. The second transistor M2 and the fourth transistor M4 may be P-type transistors. In certain other embodiments, the first level may be a low level, and the second level may be a high level. The first transistor M1, the third transistor M3, the fifth transistor M5, the sixth transistor M6 may be P-type transistors. The second transistor M2 and the fourth M4 transistor may be N-type transistors. The types of transistors, and the arrangement of the first level and the second level may be determined according to different applications and designs of the present disclosure, and should not be limited by the embodiments of the present disclosure.

It should be noted that, an N-type transistor may refer to a suitable transistor that can be turned on when the voltage applied thereon is higher than its threshold voltage, and a P-type transistor may refer to a suitable transistor that can be turned on when the voltage applied thereon is lower than its threshold voltage. The first level may refer to a voltage that may be used to turn on an N-type transistor and turn off a P-type transistor, and the second level may refer to a voltage that may be used to turn off an N-type transistor and turn on a P-type transistor. In some embodiments, the source electrode and the drain electrode of a transistor may be interchangeable. It should be noted that, the modules used in the disclosed shift register unit should not be limited to the structures described above. In certain embodiments, the structures of some modules may vary according to different applications. For example, in some embodiments, the input module may include more than one transistors. It is only required that each module is able to implement a desired function. The specific structure of a module should not be limited to the embodiments of the present disclosure.

Another aspect of the present disclosure provides a method for driving a shift register unit. The method may be used to drive the shift register units illustrated in FIGS. 3 and 4. The method may include the following steps.

In the first phase, a voltage of an effective turn-on level for the input module 310 may be applied on the second input terminal S2 to turn on the input module 310. A pulse signal of the first level may be applied on the first input terminal S1 so that the input module 310 may set the voltage at the first node PU to the first level. The input module 310 may also charge the first terminal of the energy storage module 350.

In the second phase, when the voltage at the first node PU is of the first level, the output control module 320 may be turned on. A first clock signal may be applied on the third input terminal S3, to control the output control module 320 to output a shift driving signal through the shift driving signal output terminal OUTPUT.

In the third phase, a reset signal may be applied on the fourth input terminal S4, and a voltage of the second level may be applied on the fifth input terminal S5 so that the first resetting module 330 may reset the voltage at the first node PU to the second level. The first resetting module 330 may also discharge to the first terminal of the energy storage module 350. A voltage of the second level may be applied on the sixth input terminal S6 so that the voltage at the first node PU may further be reset to the voltage applied on the sixth input terminal, by the first enhanced resetting module 340.

In and after the third phase in the same frame, the voltage at the first node PU may be of the second level. That is, the first enhanced resetting module 340 may be turned on so that the first enhanced resetting module 340 may further set the voltage at the first node PU to be the voltage applied on the sixth input terminal S6. The operation of the process may repeat and the voltage at the first node PU may change accordingly in the next frame.

That is, in the first phase, the input module 310 may be turned on to set the voltage at the first node PU to the first level and charge the energy storage module 350 at the same time. In the second phase, because the voltage at the first node PU starts at the first level, the output control module 320 may be turned on. Meanwhile, the first clock signal may be applied on the third input terminal S3, and the shift driving signal output terminal OUTPUT may output the shift driving signal. In the third phase, the first resetting module 330 may be turned on to pull down the voltage at the first node PU. The first enhanced resetting module 340 may also be turned on to continuously pull down the voltage at the first node PU.

Thus, when the shift driving signal output terminal OUTPUT outputs the shift driving signal of the first level in the second phase, because the voltage at the first node PU is of the first level, the first enhanced resetting module 340 may be turned off and the first enhanced resetting module 340 would not be affect the output control module 320 to output the shift driving signal. In the third phase, after the voltage at the first node PU is set to the second level by the first resetting module 330, the first enhanced resetting module 340 may be kept on to prevent charge accumulation at the first node PU. The voltage at the first node PU thus would not change to the first level, which causes the output control module 320 to be turned on again. Thus, no enhanced resetting control module is needed for resetting the voltage at the first node PU. Compared to conventional technology, which requires an enhanced resetting control module in a shift register unit, a smaller layout area is required for the disclosed shift register unit. It is easier for the display device incorporating the disclosed shift register unit to implement a narrow bezel design.

When used to drive a shift register unit with a second resetting module 360, as shown in FIG. 4, the disclosed method may further include the following step. For example, in the third phase, an effective turn-on signal for the second resetting module 360 may be applied on the seventh input terminal S7, and a voltage of the second level may be applied on the eighth input terminal S8, to reset the voltage outputted by the shift driving signal output terminal OUTPUT. By applying this step, the voltage outputted by the shift driving signal output terminal OUTPUT may be set to the second level, so that the shift driving signal output terminal OUTPUT would not further output any shift driving signal.

The disclosed shift register unit and the method for driving the shift register unit are now illustrated in detail using the circuit diagram, certain signals for driving the shift register unit, and the level changes at certain nodes.

Assuming in this embodiment, the first input terminal S1 and the second input terminal S2 may share the same input terminal, represented by S1. The fifth input terminal S5, the sixth input terminal S6, the eighth input terminal S8, and the ninth input terminal S9 may share the same input terminal, represented by S5. The seventh input terminal and the fourth input terminal S4 may share the same input terminal, represented by S4. The first level may be the high level, and the second level may be the low level.

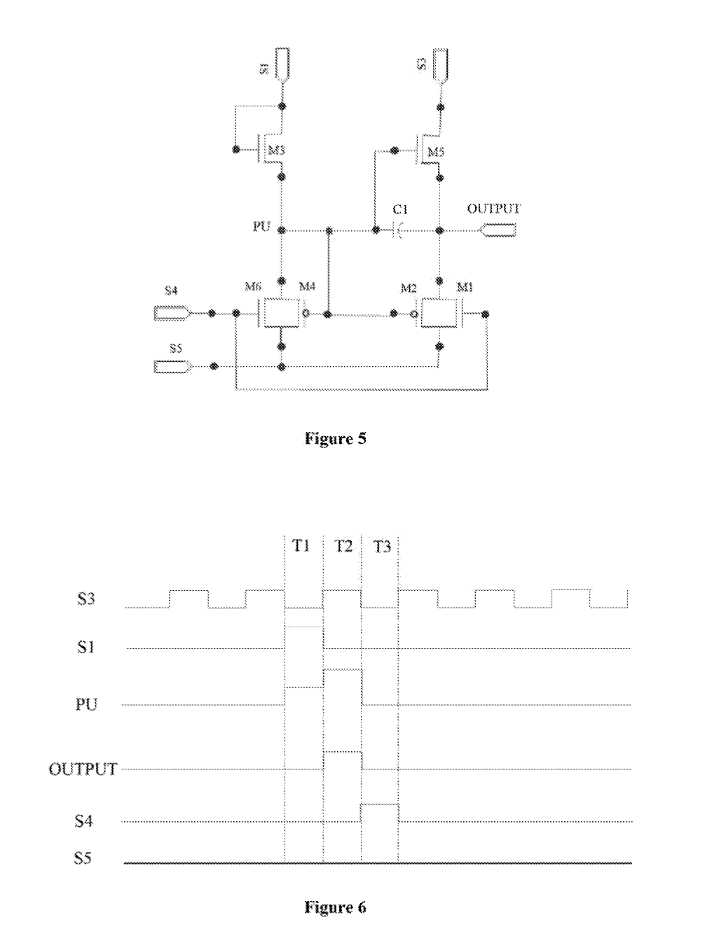

An exemplary structure of the shift register unit is shown in FIG. 5. The shift register unit, may include six transistors M1, M2, M3, M4, M5, and M6, and a capacitor C1. The shift register unit may also include a third input terminal S3, a first input terminal S1, a fourth input terminal S4, and a fifth input terminal S5. The second transistor M2 and the fourth transistor M4 may be P-type transistors. Other transistors may be N-type transistors. The width to length ratio of the channel of the third transistor M3 may be greater than the width to length ratio of the channel of the fourth transistor M4. The gate electrode of the second transistor M2, the drain electrode of the third transistor M3, the drain electrode and the gate electrode of the fourth transistor M4, the gate electrode of the fifth transistor M5, the source electrode of the sixth transistor M6, and a terminal of the capacitor C1 may be connected to node PU.

The drain electrode of the first transistor M1, the source electrode of the second transistor M2, the source electrode of the fourth transistor M4, and the drain electrode of the sixth transistor M6 may be connected to the fifth input terminal S5. The gate electrode of the first transistor M1 and the gate electrode of the sixth transistor M6 may be connected to the fourth input terminal S4. The gate electrode and the source electrode of the third transistor M3 may be connected to the first input terminal S1. The drain electrode of the second transistor M2 and the drain electrode of the fifth transistor M5 may be connected to the shift driving signal output terminal OUTPUT. The gate electrode and the source electrode of the third transistor M3 may be connected to the first input terminal S1. The source electrode of the fifth transistor M5 may be connected to the third input terminal S3.

The second transistor M2 and the fourth transistor M4 may be P-type transistors. The reason for applying a P-type second transistor M2 and a P-type fourth transistor M4 may include the follows. For example, the P-type second transistor M2 and the P-type fourth transistor M4 may ensure the voltage level at the first node PU maintain stable in a first phase and in a second phase of the operation. Also, in the third phase, the P-type second transistor M2 and the P-type fourth transistor M4 may apply enhanced resetting functions on the first node PU and the shift driving signal output terminal OUTPUT. Thus, the voltage levels at the first node and the shift driving signal output terminal OUTPUT may be desirably pulled down.

The method or operation to drive the shift register unit shown in FIG. 5 may be illustrated in the timing diagram shown in FIG. 6. In FIG. 6, the operation of the shift register unit, from the first phase T1 to the third phase T3, may be illustrated.

In the first phase T1, a voltage of high level may be applied on the first input terminal S1. At this time, the third transistor M3 may be turned on and may start to charge the first node PU, which is connected to the capacitor C1. The voltage at the first node PU may be set to be of a high level, and the fifth transistor M5 may be turned on. Because the first clock signal applied on the third input terminal S3 is of low level, the voltage outputted by the shift driving signal output terminal OUTPUT may be of low level. The voltage at the first node PU may be of high level so that the second transistor M2 and the fourth transistor M4 may be turned off. Meanwhile, a voltage of low level may be applied on the fourth input terminal S4 so that the first transistor M1 and the sixth transistor M6 may be turned off. It should be noted that, before the first phase T1, the voltage at the first node PU may be of low level and the fourth transistor M4 may be turned on. Because the width to length ratio of the channel of the third transistor M3 is greater than the width to length ratio of the channel of the fourth transistor M4, the third transistor M3 may still be able to charge the first node PU. The voltage at the first node PU may thus be charged to be of high level.

In the second phase T2, a voltage of low level may be applied on the first input terminal S1 and the fourth input terminal S4 to turn off the third transistor M3, the sixth transistor M6, and the first transistor M1. Because the voltage at the first node PU is of high level, the fourth transistor M4 and the second transistor M2 may be turned off to ensure the voltage at the first node PU would not be pulled down. That is, the voltage at the first node PU may be high to keep the fifth transistor M5 on. Because the first clock signal applied on the first input terminal S3 is of high level, the voltage outputted by the shift driving signal output terminal OUTPUT may be of high level. The shift driving signal output terminal OUTPUT may output a high-level shift driving signal. The changing of voltage outputted by the shift driving signal output terminal OUTPUT to high level may cause the voltage at the first node PU to undergo an instantaneous change. The reasons for the instantaneous change may include that, the first node PU is floating, and the voltage difference between the two terminals of the capacitor C1 would remain the same, so that the voltage at the first node PU would increase in accordance with the increase of the voltage outputted by the shift driving signal output terminal OUTPUT. The increasing of voltage at the first node PU may ensure the shift driving signal output terminal OUTPUT outputs a high-level shift driving signal with improved stability.

In the third phase T3, a voltage of low level may be applied on the first input terminal S1 to turn off the third transistor S3. Meanwhile, a voltage of high level may be applied on the fourth input terminal S4 to turn on the sixth transistor M6 and the first transistor M1. Thus, the voltage at the first node PU and the voltage outputted by the shift driving signal output terminal OUTPUT may be pulled down. The pulling down of the voltage at the first node PU may enable the second transistor M2 and the fourth transistor M4 to be turned on. After the second transistor M2 and the fourth transistor M4 are turned on, the voltage at the first node PU may be kept at a low level, so that the second transistor M2 and the fourth transistor M4 may be kept on. The enhanced resetting of the voltage at the first node PU may be realized.

As described above, in phases T1-T3, when the fourth input terminal S4 and the fifth input terminal S5 are provided with a voltage of low level, the first transistor M1 may reset the voltage outputted by the shift driving signal output terminal OUTPUT. The first transistor M1 may function as the second resetting module. When the voltage at the first node PU is of low level and a voltage of low level is applied on the fifth input terminal S5, the second transistor M2 may reset the voltage outputted by the shift driving signal output terminal OUTPUT, so that the enhanced resetting of the voltage outputted by the shift driving signal output terminal OUTPUT may be realized. The second transistor M2 may function as the second enhanced resetting module. When a voltage of high level is applied on the first input terminal S1, the third transistor M3 may write the shift driving signal to the first node PU so that the voltage at the first node PU may be set to be of high level. Meanwhile the third transistor M3 may charge the capacitor C1. The third transistor M3 may function as the input module.

When the voltage at the first node PU is of low level and the input terminal 310 is turned off, the fourth transistor M4 may reset the voltage at the first node PU to be the voltage applied on the sixth input terminal S6. The fourth transistor M4 may function as the first enhanced resetting module. When the voltage at the first node PU is of high level, the fifth transistor M5 may output the high-level shift driving signal according to the first clock signal. The fifth transistor M5 may function as the output control module. The resetting signal of the first level may be applied on the fourth input terminal S4 to control the sixth transistor M6 to set the voltage at the first node PU to be the voltage applied on the fifth input terminal S5. The voltage applied on the fifth input terminal S5, which may be of the second level. The voltage at the first node PU may be reset. The sixth transistor M6 may function as the first resetting module. The capacitor C1 may be used to store energy, e.g., electric charges. The capacitor C1 may function as the energy storing module.

Referring to FIGS. 1 and 4, compared to conventional technology, in embodiments of the present disclosure, the shift register unit may reduce the number of transistors by three, i.e., eliminating transistors M7, M8, and M9. Thus, a smaller layout area is required for the disclosed shift register unit.

Another aspect of the present disclosure provides a gate driver circuit. The gate driver circuit may include a plurality of cascading shift register units. The shift register unit may be any one of the disclosed shift register unit. It should be noted that, in some embodiments, except for the first-level shift register unit and the last-level shift register unit, the first input terminal of each shift register unit may be connected to the shift driving signal output terminal of the shift register unit of a previous level, to receive the shift driving signal outputted by the shift register unit of the previous level. The shift driving, signal output terminal of each shift register unit may be connected to the first input terminal of the shift register unit of a next level, to output the shift driving signal to the shift register unit of the next level.

Also, the shift driving signal output terminal may also be connected to the fourth input terminal of the shift register unit of the previous level to reset the shift register unit of the previous level. The first input terminal of the first-level shift register unit may be connected to a starting signal. Besides the first input terminal and the fourth input terminal, other input terminals of a shift register unit may each be connected to a corresponding signal line. Details may be referred to previous embodiments and are not repeated herein.

Another aspect of the present disclosure provides a semiconductor device. The semiconductor device may include one or more of the disclosed gate driver circuits. In some embodiments, the semiconductor device may be a display apparatus.

The display apparatus may be an electronic paper, a mobile phone, a tablet computer, a television, a monitor, a laptop computer, a digital frame, a navigation device, or any products or structures with display functions.

It should be noted that, the display apparatus may be a liquid crystal display device or other suitable types of display devices.

The disclosed shift register unit has several advantages. For example, the first resetting module may be connected to the first node and the sixth input terminal, to set the voltage at the first node to be the voltage applied on the sixth input terminal when the voltage at the first node is of the second level and the input module is turned off. Thus, when the output control module is outputting the shift driving signal, because the voltage at the first node is of the first level, the first resetting module would not be turned on. The outputting of the shift driving signal would not be adversely affected. When the voltage at the first node is set to the second level, the first enhancing module may be kept on. By applying a voltage of the second level on the sixth input terminal, charges would not accumulate at the first node, and the voltage at the first node would not change to the first level again. Thus, no enhanced resetting control module is needed to implement the enhanced resetting function on the voltage at the first node. Compared to conventional technology, which often includes an enhanced resetting control module in a shift register unit, a smaller layout area is needed for the disclosed shift register unit. It is thus easier to realize narrow bezel on the display device incorporating the disclosed shift register units.

It should be understood that the above embodiments disclosed herein are exemplary only and not limiting the scope of this disclosure. Without departing from the spirit and scope of this invention, other modifications, equivalents, or improvements to the disclosed embodiments are obvious to those skilled in the art and are intended to be encompassed within the scope of the present disclosure.

1-20. (canceled)

21. A shift register unit, comprising: an input module, a first resetting module, an energy storage module, a first enhanced resetting module, an output control module, a first input terminal, a second input terminal, a third input terminal, a fourth input terminal, a fifth input terminal, a sixth input terminal, a shift driving signal output terminal, and a first node, wherein:
a first terminal of the energy storage module is connected to the first node;
the input module is connected to the first node, the first input terminal, and the second input terminal;
the output control module is connected to the first node, the third input terminal, and the shift driving signal output terminal;
the first resetting module is connected to the first node, the fourth input terminal, and the fifth input terminal; and
the first enhanced resetting module is connected to the first node and the sixth input terminal.

22. The shift register unit according to claim 21, wherein:
when an effective turn-on voltage is applied at the second input terminal, the input module turns on to write a pulse signal of a first level applied by the first input terminal to the first node, sets a voltage at the first node to the first level, and charges the first terminal of the energy storage module;
the output control module outputs a shift driving signal to the shift driving signal output terminal based on a first clock signal applied on the third input terminal when a voltage at the first node is of the first level;
when a resetting signal is applied on the fourth input terminal, the first rescuing module sets the voltage at the first node to a second level based on a voltage of the second level applied on the fifth input terminal; and
when the voltage at the first node is of the second level and the input module is turned off, the enhanced resetting module sets the voltage at the first node to be of a level of a voltage applied on the sixth input terminal.

23. The shift register unit according to claim 22, wherein the fifth input terminal and the sixth input terminal are a same input terminal.

24. The shift register unit according to claim 23, further comprising: a second resetting module, a seventh input terminal, and an eighth input terminal, a second terminal of the energy storage module being connected to the shift driving signal output terminal, the second resetting module being connected to the shift driving signal output terminal, the seventh input terminal, and the eighth input terminal, wherein:
when an effective turn-on voltage of the second resetting module is applied on the seventh input terminal and a voltage of the second level is applied on the eighth input terminal, the second rescuing module sets a voltage outputted by the shift driving signal output terminal to the second level.

25. The shift register unit according to claim 24, wherein: the eighth input terminal is a same input terminal with one or more of the fifth input terminal and the sixth input terminal.

26. The shift register unit according to claim 24, wherein:
the seventh input terminal and the fourth input terminal are a same input terminal; and
the effective turn-on voltage of the second resetting module and the resetting signal are of first level.

27. The shift register unit according to claim 24, wherein the second resetting module comprises a first transistor, being N-type, a gate electrode of the first transistor being connected to the seventh input terminal, a source electrode of the first transistor being connected to the shift driving signal output terminal, and a drain electrode of the first transistor being connected to the eighth input terminal, a turn-on level of the first transistor being the first level.

28. The shift register unit according to claim 24, further comprising: a second enhanced resetting module and a ninth input terminal, wherein:
the second enhanced resetting module is connected to the first node, the ninth input terminal, and the shift driving signal output terminal; and
the second enhanced resetting module resets the voltage outputted by the shift driving signal output terminal to the second level when the voltage at the first node is of the second level and the ninth input terminal is applied with a voltage of the second level.

29. The shift register unit according to claim 28, wherein: the ninth input terminal is a same input terminal with one or more of the fifth input terminal and the sixth input terminal.

30. The shift register unit according to claim 28, wherein: the second enhanced resetting module comprises a second transistor, being P-type, a gate electrode of the second transistor being connected to the first node, a drain electrode of the second transistor being connected to the shift driving signal output terminal, a source electrode of the second transistor being connected to the ninth input terminal, and a turn-on level of the second transistor being the second level.

31. The shift register unit according to claim 22, wherein: the input module comprises a third transistor, being N-type, a gate electrode of the third transistor being connected to the second input terminal, and a source electrode of the third transistor being connected to the first input terminal; or the gate electrode of the third transistor being connected to the first input terminal, and the source electrode of the third transistor being connected to the second input terminal, a drain electrode of the third transistor being connected to the first node, and a turn-on level of the third transistor being the first level.

32. The shift register unit according to claim 30, wherein: the first enhanced resetting module comprises a fourth transistor, being P-type, a gate electrode and a drain electrode of the fourth transistor being connected to the first node, a source electrode of the fourth transistor being connected to the sixth input terminal, a width to length ratio of the channel of the fourth transistor being less than a width to length ratio of the channel of the third transistor, and a turn-on level of the fourth transistor being the second level.

33. The shift register unit according to claim 22, wherein: the output control module comprises a fifth transistor, being N-type, a source electrode of the fifth transistor being connected to the third input terminal, a gate electrode of the fifth transistor being connected to the first node, a drain electrode of the fifth transistor being connected to the shift driving signal output terminal, and a turn-on level of the fifth transistor being the first level.

34. The shift register unit according to claim 22, wherein: the first rescuing module comprises a sixth transistor, being N-type, a source electrode of the sixth transistor being connected to the first node, a drain electrode of the sixth transistor being connected to the fifth input terminal, a gate electrode of the sixth transistor being connected to the fourth input terminal, a turn-on level of the sixth transistor being the first level.

35. The shift register unit according to claim 22, wherein:
the first input terminal and the second input terminal are a same input terminal; and
an effective turn-on voltage of the input terminal is of the first level.

36. The shift register unit according to claim 22, wherein: the energy storage unit is a capacitor.

37. The shift register unit according to claim 21, wherein the first level is a high level and the second level is a low level.

38. A method for driving the Shift register unit according to claim 21, comprising:
in a first phase, applying a voltage of an effective turn-on level for the input module on the second input terminal to turn on the input module, and applying a pulse signal of the first level on the first input terminal so that the input module sets the voltage at the first node to the first level, and the input module charging the first terminal of the energy storage module;
in a second phase, when the voltage at the first node is of the first level, turning on the output control module, applying a first clock signal on the third input terminal to control the output control module to output a shift driving signal through the shift driving signal output terminal; and
in a third phase, applying a reset signal on the fourth input terminal and applying a voltage of the second level on the fifth input terminal so that the first resetting module resets the voltage at the first node to the second level, and the first resetting module discharging to the first terminal of the energy storage module,
wherein in and after the third phase in a same frame, the voltage at the first node id of the second level, turning on the first enhanced resetting module so that the first enhanced resetting module sets the voltage at the first node to be the voltage applied on the sixth input terminal.

39. A gate driver circuit comprising a plurality of cascading shift register units according to claim 21.

40. A semiconductor device, comprising one or more of the gate driver circuits according to claim 39.
